(19) United States
(12) Patent Application Publication
(10) Pub. No.: US 2026/0221716 A1
(43) Pub. Date: Jul. 30, 2026

(54) SEMICONDUCTOR LASER DEVICE

(71) Applicant: ams-OSRAM International GmbH, Regensburg (DE)

(72) Inventors: Andreas FRÖHLICH, Regensburg (DE); Jörg Erich SORG, Regensburg (DE); Nicole BERNER, Walderbach (DE); Erik HEINEMANN, Regensburg (DE); Jan MARFELD, Regensburg (DE); Tobias HAUPELTSHOFER, Breitenbrunn (DE)

(73) Assignee: ams-OSRAM International GmbH, Regensburg (DE)

(21) Appl. No.: 19/149,043

(22) PCT Filed: Jan. 9, 2024
(86) PCT No.: PCT/EP2024/050361

§ 371 Date: Jul. 17, 2025

(30) Foreign Application Priority Data
Jan. 26, 2023 (DE) 102023101941.4

(51) Int. Cl. H01S 5/023; H01S 5/40

(52) U.S. Cl. CPC H01S 5/023; H01S 5/4025

(57) ABSTRACT

The invention relates to a semiconductor laser device having a plurality of semiconductor lasers, wherein the semiconductor device has a mounting support with a mounting surface; the semiconductor lasers are located on the mounting surface; the semiconductor device has at least two driver components for controlling the semiconductor lasers; and the at least two driver components are arranged one on top of the other seen in a vertical direction that extends perpendicularly to the mounting surface.

### CROSS-REFERENCE TO RELATED APPLICATIONS

The present application is a national stage entry from International Application No. PCT/EP2024/050361, filed on Jan. 9, 2024, published as International Publication No. WO 2024/156498 A1 on Aug. 2, 2024, and claims priority to German Patent Application No. 10 2023 101 941.4, filed Jan. 26, 2023, the disclosures of all of which are hereby incorporated by reference in their entireties.

### FIELD

The present application relates to a semiconductor laser device with a plurality of semiconductor lasers.

### BACKGROUND

Various laser applications require concepts that provide a compact design and can reliably emit radiation, in particular in pulsed form, from two or more lasers from as an exit area that is as small as possible.

One task is to specify a semiconductor laser device that is compact and suitable for emitting radiation with a short pulse duration from a small exit area during operation.

This task is solved, inter alia, by a semiconductor laser device with the features of claim 1. Further embodiments and expediencies are the subject of the dependent patent claims.

### SUMMARY

A semiconductor laser device with a plurality of semiconductor lasers is specified. The semiconductor laser device is configured, for example, as a surface-mounted device (smd).

The semiconductor lasers are, for example, edge-emitting semiconductor lasers. The semiconductor lasers can have one or more emission regions. An emission region is, for example, a ridge-shaped region (also referred to as a ridge), whereby in the case of several emission regions at least some or all of the emission regions of a semiconductor laser can, for example, be electrically contactable independently of one another.

For example, the semiconductor lasers each comprise at least one, at least two or at least three and/or at most 50 or at most 20 or at most 10 emission regions. The number of emission areas may be the same or different among the semiconductor lasers.

The semiconductor lasers are intended, for example, to generate radiation in the visible spectral range, such as in the red, green or blue spectral range. Alternatively or additionally, at least one of the semiconductor lasers can also be provided for generating radiation in the ultraviolet or infrared spectral range. For example, the semiconductor laser device comprises three semiconductor lasers emitting radiation in the red, green and blue spectral range, so that the semiconductor laser device as a whole is an RGB laser component.

According to at least one embodiment of the semiconductor laser device, the semiconductor laser device comprises a mounting carrier with a mounting surface. For example, all contacts for the external electrical contacting of the semiconductor laser device are arranged on a side of the mounting carrier opposite the mounting surface.

For example, the mounting carrier contains a ceramic, such as aluminum nitride. Ceramic materials have an advantageous high thermal conductivity. Alternatively, the mounting carrier can comprise a semiconductor material or a composite material, such as a class FR4 composite material. The mounting carrier may have one or more wiring levels. The electrical connection between the contacts and the at least one wiring level can be made via vias in the mounting carrier.

According to at least one embodiment of the semiconductor laser device, the semiconductor lasers are arranged on the mounting surface. Further elements may be arranged between the mounting surface and the semiconductor lasers, for example a submount and/or a module carrier for the semiconductor lasers. For example, the semiconductor lasers are each electrically conductively connected to at least one wiring level of the mounting carrier.

According to at least one embodiment of the semiconductor laser device, the semiconductor laser device comprises at least two driver components for controlling the semiconductor lasers. A driver component comprises, for example, an integrated circuit and can be present in unpackaged form as a bare semiconductor chip or in packaged form.

The driver components are configured, for example, to operate the associated semiconductor laser, for example in pulsed mode, possibly in conjunction with other passive electronic components such as capacitors or resistors outside the driver components.

According to at least one embodiment of the semiconductor laser device, the at least two driver components are arranged one above the other in a vertical direction perpendicular to the mounting surface. In other words, one of the driver components is located at a greater distance from the mounting surface than the other driver component. In plan view of the mounting surface, the two driver components overlap at least in places or completely.

In at least one embodiment of the semiconductor laser device, the semiconductor laser device comprises a plurality of semiconductor lasers and a mounting carrier with a mounting surface, wherein the semiconductor lasers are arranged on the mounting surface. The semiconductor laser device comprises at least two driver components for driving the semiconductor lasers, wherein the at least two driver components are arranged one above the other in a vertical direction perpendicular to the mounting surface.

The control of the semiconductor lasers as a whole is therefore not integrated into one driver component, but rather divided into at least two driver components. In particular, each semiconductor laser can be assigned exactly one driver component, so that the number of driver components corresponds to the number of semiconductor lasers.

It has turned out that by arranging the driver components one above the other, a design can be achieved for the semiconductor laser device that is characterized by a particularly small footprint in plan view of the mounting surface. This results in a particularly compact design for the semiconductor laser device with driver components already integrated into the semiconductor laser device. Furthermore, very short analog connection paths can be achieved between the semiconductor lasers and the associated driver components. This results in a low impedance, which simplifies high-frequency modulation of the semiconductor lasers.

A main emission direction of the semiconductor laser device can be parallel, oblique or perpendicular to the mounting surface of the mounting carrier. Conveniently, all semiconductor lasers emit along the main emission direction. In the event that the radiation is emitted parallel to the mounting surface of the mounting carrier, the semiconductor laser device is configured as a so-called “sidelooker”.

In the context of the present application, the terms “perpendicular” and “parallel” also include minor production-related tolerances, for example of at most 10° or at most 5°.

According to at least one embodiment of the semiconductor laser device, the mounting carrier comprises a recess in which one of the driver components is arranged. In particular, a vertical extent of the recess is greater than a vertical extent of the associated driver component, so that the driver component is arranged completely within the recess. By means of the recess in the mounting carrier, one of the driver components can be integrated into the semiconductor laser device without increasing the vertical dimension of the semiconductor laser device. Optionally, the driver component can be completely or at least partially surrounded by a casing in the recess. The stability of the mechanical connection between the driver component and the mounting carrier can be increased by means of such an enclosure.

According to at least one embodiment of the semiconductor laser device, the semiconductor laser device comprises a carrier body, with at least one of the driver components being arranged in a recess in the carrier body. In particular, the carrier body is attached to the mounting surface. In particular, the materials listed for the mounting carrier can be used for the carrier body. In particular, the carrier body provides both a mechanical and an electrical connection between the associated driver component and one or more wiring levels of the mounting carrier. Two or more recesses can also be formed in the carrier body to accommodate a driver component. For example, a carrier body comprises two recesses that extend into the carrier body from opposite sides.

For example, a carrier body comprises both contact points for electrical contacting of the driver component and contact points for electrical connection of the driver component to at least one of the wiring levels of the mounting carrier. Furthermore, a carrier body can, for example, comprise vias that extend vertically through the carrier body.

According to at least one embodiment of the semiconductor laser device, the carrier body and the semiconductor lasers are arranged next to each other on the mounting surface. In particular, there is no overlap between the carrier body and the semiconductor lasers when viewed from above on the mounting surface.

According to at least one embodiment of the semiconductor laser device, the semiconductor laser device comprises a further carrier body, at least one of the driver components being arranged in a recess in the further carrier body. In particular, the carrier body and the further carrier body are arranged one above the other on the mounting surface. In plan view of the mounting surface, the carrier body and the further carrier body therefore overlap completely or at least in certain areas. The further carrier body may have one or more of the features described in connection with the carrier body.

According to at least one embodiment of the semiconductor laser device, the semiconductor laser device comprises a cover in which the semiconductor lasers of the semiconductor laser device are arranged, in particular in a hermetically sealed manner. For example, the cover forms a cavity in which the semiconductor lasers are arranged. The cover is transmissive at least in an exit area in which the radiation generated by the semiconductor lasers emerges from the semiconductor laser device during operation of the semiconductor laser device. For example, the cover contains a glass, a plastic and/or a ceramic. The cover can be made in one piece or in several pieces.

According to at least one embodiment of the semiconductor laser device, the cover and the carrier body are arranged next to each other on the mounting surface. In particular, the cover does not cover the driver components. In this way, a particularly low overall height can be achieved in the vertical direction.

For example, the vertical dimension of the semiconductor laser device in the area of the cover is greater than or equal to the vertical dimension in the area of the driver components. Stacking the driver components therefore does not increase the maximum height of the semiconductor laser device in the vertical direction. The base area of the semiconductor laser device in plan view of the mounting surface can thus be reduced without increasing the maximum vertical dimension of the semiconductor laser device.

According to at least one embodiment of the semiconductor laser device, exactly one of the driver components is assigned to each semiconductor laser of the semiconductor laser device. The driver components can thus be specifically adapted to the semiconductor laser to be controlled in each case.

According to at least one embodiment of the semiconductor laser device, the semiconductor laser device comprises a module carrier. For example, the module carrier together with the cover forms the hermetically sealed area in which the semiconductor lasers are arranged.

When manufacturing the semiconductor laser device, the semiconductor lasers with the module carrier and the cover can be attached to the mounting surface of the mounting carrier as a prefabricated laser module. Before mounting, the semiconductor lasers can be tested while already installed on the module carrier. This ensures that the mounting carrier is fitted with a functional laser module. The production yield can thus be optimized.

According to at least one embodiment of the semiconductor laser device, the semiconductor laser device comprises a submount with an attachment surface, wherein at least one of the semiconductor lasers is attached to the attachment surface and is attached to the mounting surface via the submount. The submount is, for example, attached directly to the mounting surface or, if necessary, attached to the mounting carrier via the module carrier. The attachment surface can run parallel, at an angle or perpendicular to the mounting surface.

According to at least one embodiment of the semiconductor laser device, the semiconductor laser device comprises a further submount with a further attachment surface, wherein a further semiconductor laser of the plurality of semiconductor lasers is attached to the mounting surface via the further submount. The submount may have one or more of the features mentioned in connection with the submount.

A ceramic, for example, is suitable for the submount. Alternatively, a semiconductor material can also be used.

According to at least one embodiment of the semiconductor laser device, the attachment surface of the submount and the further attachment surface of the further submount face each other. As a result, particularly small distances between the semiconductor lasers arranged on the respective submounts can be achieved with high precision.

According to at least one embodiment of the semiconductor laser device, the attachment surface runs perpendicular to the mounting surface of the mounting carrier. For example, two semiconductor lasers are arranged one above the other on an attachment surface extending perpendicularly to the mounting surface of the mounting carrier, as viewed in the vertical direction.

According to at least one embodiment of the semiconductor laser device, the submount comprises a contact coating, whereby the contact coating on the attachment surface forms at least two connection surfaces for electrical contacting of the associated semiconductor laser. Furthermore, the contact coating forms at least two electrical contact surfaces via which the submount is electrically connected to the mounting carrier. In particular, the at least two electrical contact surfaces each run parallel to the mounting surface of the mounting carrier. The electrical contact surfaces can be arranged completely or at least partially on a mounting side surface of the submount and/or completely or at least partially on a side of the submount opposite the mounting side surface. The contact coating is therefore arranged, in particular in structured form, on the attachment surface and additionally on one or two side surfaces extending perpendicular to the attachment surface.

According to at least one embodiment of the semiconductor laser device, the emission regions of all semiconductor chips are arranged within an ellipse with a longitudinal axis of at most 1000 μm or at most 500 μm or at most 250 μm and/or with a transverse axis of at most 200 μm or at most 100 μm or at most 50 μm. The semiconductor laser device is therefore a good approximation of a point light source. This reduces the complexity and size of an optical element downstream of the semiconductor laser device. If the main emission direction runs parallel to the mounting surface, the longitudinal axis is arranged parallel or perpendicular to the mounting surface, for example. If the main emission direction is perpendicular to the mounting surface, the longitudinal axis and the transverse axis are arranged parallel to the mounting surface.

According to at least one embodiment of the semiconductor laser device, the semiconductor laser device is adapted to emit laser pulses with a pulse duration of at most 10 ns or at most 5 ns or at most 3 ns. For example, a rise time is between 100 ps and 800 ps inclusive. Such short pulse durations and short rise times can be achieved by the compact design of the semiconductor laser device with integrated driver components in the arrangement described.

When viewed from above on the mounting surface, the semiconductor laser device comprises an extension that is larger in a longitudinal direction, for example at least twice as large or at least three times as large, as in a transverse direction running perpendicular to it. For example, the longitudinal direction of the semiconductor laser device runs along the main emission direction when viewed from above on the mounting surface. Such an elongated design seen along the main emission direction is particularly suitable for installation in a temple arm of glasses. For other applications, however, the semiconductor laser device can also have other dimensions.

The semiconductor laser device described here is particularly suitable for use as a compact laser light source in portable devices, for example for projection applications, head-up displays, augmented reality displays or virtual reality displays. For example, the semiconductor laser device can be integrated into a pair of glasses, in particular a temple arm.

Features described in connection with at least one embodiment can also be combined with other features described in connection with at least one embodiment, as long as these features are not mutually exclusive.

Further embodiments and functionalities are shown in the following description of the exemplary embodiments in conjunction with the figures.

### BRIEF DESCRIPTION OF THE DRAWINGS

In the Figures:

FIGS. 1A to 1C show an exemplary embodiment of a semiconductor laser device in a perspective view (FIG. 1A), a perspective sectional view (FIG. 1B) and a schematic sectional view (FIG. 1C);

FIGS. 2A to 2C show an exemplary embodiment of a semiconductor laser device by means of a detail of a perspective view (FIG. 2A), a sectional view along the line AA′ shown in FIG. 2A (FIG. 2B) and a schematic sectional view (FIG. 2C); and

FIGS. 3A and 3B show a schematic top view of a laser module of a semiconductor laser device (FIG. 3B) and an associated sectional view along the line BB′ shown in FIG. 3B (FIG. 3A).

### DETAILED DESCRIPTION

The figures are schematic representations and are therefore not necessarily true to scale. In particular, comparatively small elements or layer thicknesses may be shown in exaggerated size for improved representation and/or better understanding. Identical, similar or similarly acting elements are each provided with the same reference symbols in the figures.

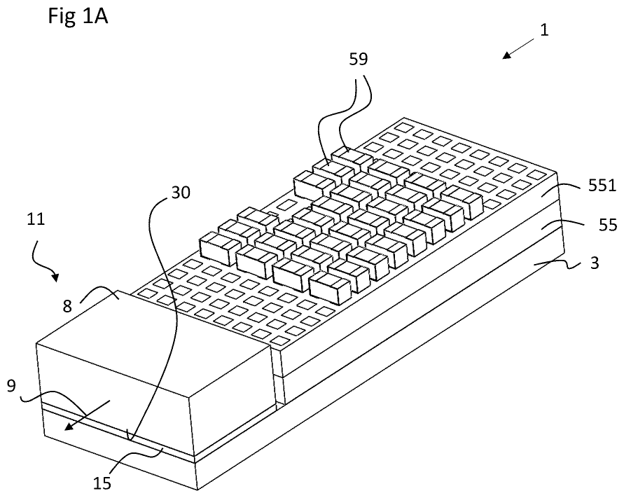

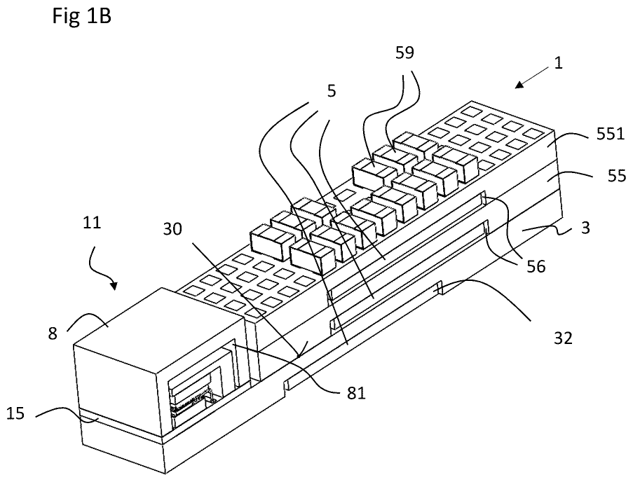

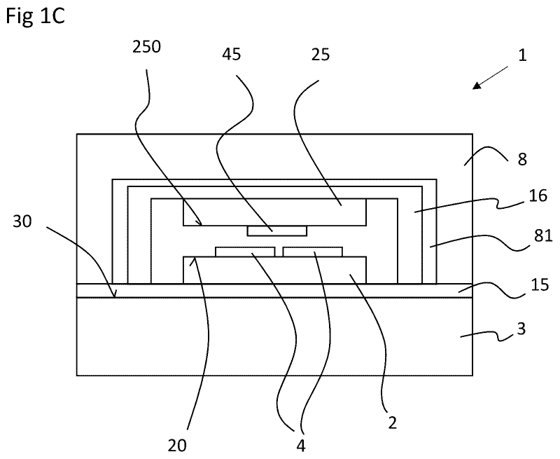

In the exemplary embodiment shown in FIGS. 1A to 1C, the semiconductor laser device 1 comprises a plurality of semiconductor lasers 4 and a mounting carrier 3 with a mounting surface 30. The semiconductor lasers 4 are arranged on the mounting surface 30, wherein the semiconductor lasers 4 are in particular each designed as unhoused semiconductor laser chips. The semiconductor laser device also comprises, by way of example, three driver components 5 for controlling the semiconductor lasers 4. Seen in a vertical direction perpendicular to the mounting surface 30 of the mounting carrier, the driver components 5 are arranged one above the other. A ceramic, such as aluminum nitride with one or more wiring levels, is suitable for the mounting carrier 3.

The mounting carrier 3 comprises a recess 32 in which one of the driver components 5 is arranged.

Furthermore, the semiconductor laser device comprises a carrier body 55 and a further carrier body 551. The further carrier body 551 is arranged on the side of the carrier body 55 facing away from the mounting carrier 3. One of the driver components 5 is arranged in each of a recess 56 of the carrier body 55 and a recess 56 of the further carrier body 551. The vertical extent of the recesses in the mounting carrier 3 and in the carrier bodies 55, 551 is in each case so large that the driver components 5 can be placed completely within the associated recess.

The driver components 5 in the carrier body 55 or the further carrier body 551 are each electrically conductively connected to at least one wiring level on the mounting surface 30 of the mounting carrier 3 via the associated carrier body. The driver components 5 are, for example, bare semiconductor chips or packaged semiconductor chips that are electrically conductively connected via an array of connecting balls (ball grid array, BGA) to the associated carrier body 55, 551 or the mounting carrier 3.

In the associated recesses 32, 56, the driver components 5 can be completely or at least partially surrounded by a casing, for example an epoxy. The mechanical stability of the connection between the driver component and the associated carrier body 55 or the mounting carrier 3 can thus be increased.

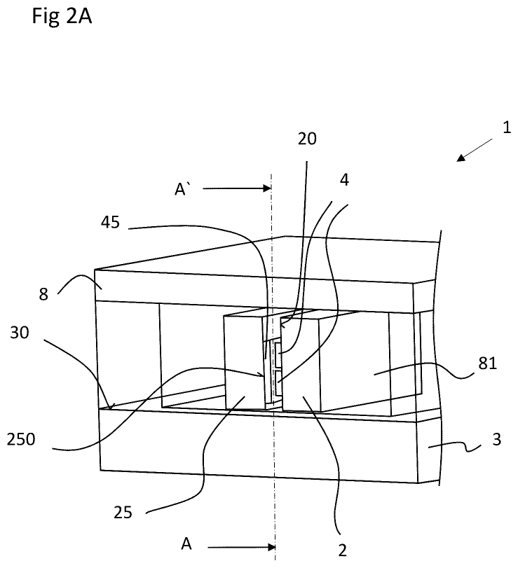

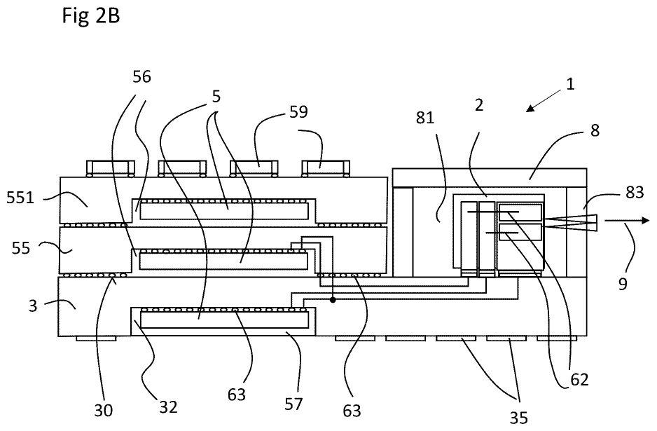

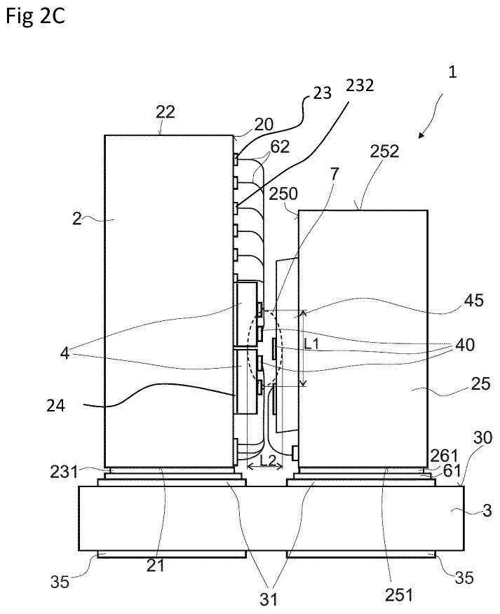

Such a casing 57 is shown as an example in FIG. 2B for the recess 32 of the mounting carrier 3 and can also be used for the other exemplary embodiments.

Each driver component 5 is used to electrically control exactly one semiconductor laser 4.

For example, the driver components 5 are each set up to operate the associated semiconductor laser 4 in pulsed mode with a pulse width of at most 10 nm or at most 5 nm or at most 3 nm.

Electronic components in the form of capacitors 59 are arranged on the further carrier body 551. Further passive electronic components such as capacitors or resistors can also be integrated into the carrier body 55 and/or the further carrier body 551 and/or the mounting carrier 3.

The carrier body 55, the further carrier body 551 and/or the mounting carrier 3 each have vias that extend completely through the relevant element in the vertical direction.

On the side of the mounting carrier 3 opposite the mounting surface 30, the semiconductor laser device 1 comprises contacts 35 for the external electrical contacting of the semiconductor laser device. For example, the number of contacts 35 of the semiconductor laser device 1 is between 10 and 200 inclusive, for example about 100 to 120.

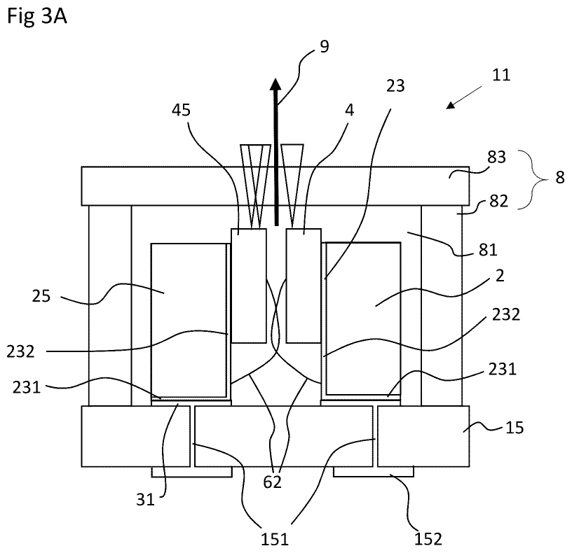

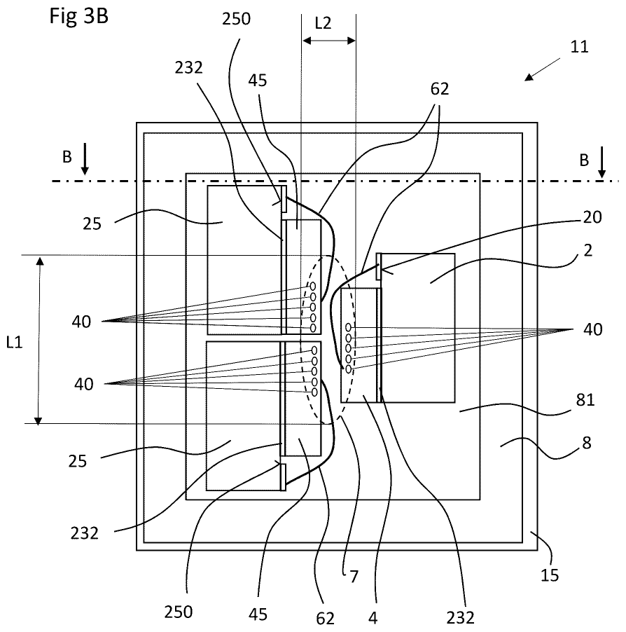

In the exemplary embodiment shown, a main emission direction 9 runs parallel to the mounting surface 30 of the mounting carrier 3. However, as described in connection with FIGS. 3A and 3B, the main emission direction can also run at an angle or perpendicular to the mounting surface 30.

The semiconductor laser device 1 further comprises a cover 8. The cover 8 forms a cavity 81 in which the semiconductor lasers 4 are arranged in a hermetically sealed manner.

The cover 8 and the carrier body 55 are arranged next to each other on the mounting surface 30. The driver components 5 are therefore located outside the cover 8.

The semiconductor laser device 1 has its maximum height, i.e. its maximum vertical extension, in the area of the cover 8. The maximum height of the semiconductor laser device 1 is therefore not increased despite the stacking of the driver components 5. By stacking the driver components 5, the base area of the semiconductor laser device 1 can therefore be minimized in plan view of the mounting surface without negatively affecting the overall height of the semiconductor laser device 1.

In the exemplary embodiment shown, the semiconductor laser device 1 is optimized with regard to the smallest possible transverse extent perpendicular to the main emission direction 9. For example, a longitudinal expansion of the semiconductor laser device along the main emission direction 9 is at least twice as large as the transverse extent.

For example, the height of the semiconductor laser device 1 in the vertical direction is at most 5 mm or at most 4 mm or at most 3 mm. The transverse extension of the semiconductor laser device is, for example, at most 10 mm or at most 8 mm or at most 6 mm. The longitudinal extent of the semiconductor laser device is, for example, at most 25 mm or at most 20 mm or at most 18 mm.

As illustrated in FIG. 1C, the semiconductor laser device 1 comprises two semiconductor lasers 4, which are arranged next to each other on an attachment surface 20 of a submount 2. A further semiconductor laser 45 of the semiconductor lasers 4 is arranged on a further submount 25 with a further attachment surface 250. The attachment surface 20 and the further attachment surface 250 face each other. This allows the distance between the semiconductor lasers 4 and the further semiconductor laser 45 to be minimized. The further submount 25 is connected to the mounting carrier 3 via a module frame 16. In the exemplary embodiment shown, the main emission direction 9, the attachment surface 20 and the further attachment surface 250 run parallel to the mounting surface 30 of the mounting carrier 3. Deviating from this, however, the attachment surfaces 20, 250 can also run at an angle or perpendicular to the mounting surface 30. This is described in more detail in connection with the following exemplary embodiments.

In the exemplary embodiment shown in FIGS. 1A to 1C, the semiconductor lasers 4, 45 and the cover 8 are part of a laser module 11. The laser module 11 comprises a module carrier 15. The module carrier 15 is attached to the mounting surface 30 of the mounting carrier 3. During the manufacture of the semiconductor laser device 1, the laser module 11 can be prefabricated and tested before being fitted to the mounting carrier 3. Furthermore, the part of the semiconductor laser device 1 with the driver components 5 can also be tested without the laser module 11. The yield of functional semiconductor laser devices 1 can thus be maximized during production.

However, as described in connection with the following exemplary embodiment, a module carrier 15 is not absolutely necessary. Rather, the semiconductor lasers 4, 45 with the associated submounts 2, 25 can also be mounted directly on the mounting carrier 3.

The hermetic encapsulation can be achieved, for example, via a connection between the cover 8 and the module carrier 15 or, in particular in the absence of a module carrier, between the cover 8 and the mounting carrier 3, for example via a soldering process, such as a stack soldering process or via a jetting process, for example using AuSn.

For the electrical connection between the carrier bodies 55, 551 and the mounting carrier 3 and/or between the carrier body 55 and the further carrier body 551 and/or for the connection between the laser module 11 and the mounting carrier 3, soldering, for example AuSn soldering or sintering, for example Ag sintering, is suitable. Sintered connections are characterized by particularly good stability against high temperatures, such as those that can occur when the semiconductor laser device 1 is mounted by soldering.

During operation of the semiconductor laser device 1, the radiation can emerge from a comparatively small exit area 7, in particular also in the case of several emission regions 40 per semiconductor laser 4. This is explained in more detail in connection with FIG. 2B and FIG. 3B and also applies to the present exemplary embodiment.

The exemplary embodiment shown in FIGS. 2A to 2C essentially corresponds to the exemplary embodiment described in connection with FIGS. 1A to 1C. In contrast to the exemplary embodiment shown in FIGS. 1A to 1C, the semiconductor laser device 1 does not have a module carrier 15. However, such a module carrier can also be used in this exemplary embodiment as described in connection with FIGS. 1A to 1C.

Furthermore, the exemplary embodiment differs from the exemplary embodiment described in FIGS. 1A to 1C in that the attachment surface 20 of the submount 2 and the further attachment surface 250 of the further submount 25 run perpendicular to the mounting surface 30.

Seen along the vertical direction, the semiconductor lasers 4 are arranged one above the other on the submount 20. As in the exemplary embodiment of FIGS. 1A to 1C, the main emission direction 9 runs parallel to the mounting surface 30 of the mounting carrier 3.

The submount 2 comprises a contact coating 23. The contact coating 23 forms connection surfaces 232 on the attachment surface 20 for the electrical contacting of the individual emission areas of the semiconductor lasers 4. Furthermore, the contact coating forms laser mounting areas 24 on which the semiconductor lasers 4 are arranged.

The electrical contact between the semiconductor lasers 4 and the connection surfaces 232 is made via wire bond connections 62.

The connection surfaces 232 are each assigned an electrical contact surface 231 for the electrical connection to the mounting carrier 3. The electrical contact surfaces 231 run parallel to the mounting surface 30 of the mounting carrier 3. In the exemplary embodiment shown, the electrical contact surfaces 231 are arranged on a mounting side surface 21 of the submount 2.

Analogous to the submount 20, the further submount 25 comprises a further attachment surface 250, a further mounting side surface 251, a further side surface 252 and a further contact surface 261.

The contact surfaces 231 are connected to an associated connecting surface 31 of the mounting carrier 3 via a bonding agent 61, for example a solder, or via sintering.

Alternatively or additionally, the electrical contact surfaces 231 can also be arranged on a side surface 22 of the submount 2 opposite the mounting side surface 21. Electrical contact surfaces arranged on this side surface 22 can, for example, be connected to associated connecting surfaces 31 of the mounting carrier via wire bond connections.

The submount 2 and the further submount 25 can be arranged next to each other directly on the mounting carrier 3 or, if necessary, directly on the module carrier 15. In this way, a small distance between the semiconductor lasers 4 and the further semiconductor laser 45 can be achieved in a simple and reliable manner.

An exit area 7 in the form of an ellipse is shown schematically in FIG. 2C. A longitudinal axis L1 is preferably less than 250 μm, a transverse axis L2 is preferably less than 50 μm. In contrast to the previous exemplary embodiment, the longitudinal axis L1 does not run parallel, but perpendicular to the mounting surface 30.

In the exemplary embodiment shown, the cover 8 comprises a radiation transmissive window 83 at least in the area of the exit area 7 and can also be opaque to radiation in some areas.

FIGS. 3A and 3B show an exemplary embodiment of a laser module 11 which can alternatively be used as a laser module in the exemplary embodiment of a semiconductor laser device according to FIGS. 1A to 1C.

In contrast to the previous exemplary embodiments, the main emission direction 9 in this exemplary embodiment runs perpendicularly or obliquely to the mounting surface 30 of the mounting carrier 3. The cover 8 comprises, for example, a radiation-opaque frame part 82 and a window 83.

The semiconductor laser device 1 comprises a submount 2, on which a semiconductor laser 4 is arranged, and two further submounts 25, each with a further semiconductor laser 45. However, as in the preceding embodiments, two semiconductor lasers 4 can also be arranged on one submount 2, 25. The mounting of the semiconductor lasers 4, 45 on the associated submount can be configured as described in connection with FIGS. 2A to 2C.

The connecting surfaces 31 are connected to module contacts 152 on the side of the module carrier 15 facing away from the semiconductor lasers 4 via vias 151. The semiconductor lasers 4 can be electrically conductively contacted with a wiring level on the mounting carrier via the module contacts 152. Such electrical contacting is also expediently used in the exemplary embodiment described with reference to FIGS. 1A to 1C.

FIG. 3B also illustrates the individual emission areas 40 of the semiconductor lasers 4, 45 within the exit area 7. This arrangement preferably also applies to the other embodiments.

Deviating from the exemplary embodiment shown, the submount 2 and the further submounts 25 can be attached directly to the mounting carrier 3 as described in connection with FIGS. 2A to 2C without a module carrier 15 arranged in between.

The invention is not limited by the description based on the embodiments. Rather, the invention includes any new feature as well as any combination of features, which includes in particular any combination of features in the patent claims, even if this feature or combination itself is not explicitly stated in the patent claims or the embodiments.

1. A semiconductor laser device comprising a plurality of semiconductor lasers, wherein
the semiconductor laser device comprises a mounting carrier with a mounting surface,
the semiconductor lasers are arranged on the mounting surface,
the semiconductor laser device comprises at least two driver components for driving the semiconductor lasers, and
the at least two driver components are arranged one above the other as seen in a vertical direction perpendicular to the mounting surface;
wherein
(i) the mounting carrier comprises a recess in which one of the driver components is arranged,
and/or
(ii) the semiconductor laser device comprises a carrier body, wherein at least one of the driver components is arranged in a recess of the carrier body and the carrier body is fastened to the mounting surface.

2. The semiconductor laser device according to claim 1,
wherein the carrier body and the semiconductor lasers are arranged next to each other on the mounting surface.

3. The semiconductor laser device according to claim 1,
wherein the semiconductor laser device comprises a further carrier body, wherein at least one of the driver components is arranged in a recess of the further carrier body and wherein the carrier body and the further carrier body are arranged one above the other on the mounting surface.

4. The semiconductor laser device according to claim 1, wherein the semiconductor laser device comprises a cover in which the semiconductor lasers of the semiconductor laser device are hermetically sealed.

5. The semiconductor laser device according to claim 4, wherein the cover and the carrier body are arranged next to each other on the mounting surface.

6. The semiconductor laser device according to claim 1, wherein each semiconductor laser of the semiconductor laser device is assigned exactly one of the driver components.

7. The semiconductor laser device according to claim 1, wherein the semiconductor laser device has a submount with an attachment surface, wherein at least one of the semiconductor lasers is attached to the attachment surface and is attached to the mounting surface via the submount.

8. The semiconductor laser device according to claim 7, wherein the semiconductor laser device comprises a further submount with a further attachment surface, wherein a further semiconductor laser of the plurality of semiconductor lasers is mounted on the mounting surface via the further submount.

9. The semiconductor laser device according to claim 8, wherein the attachment surface and the further attachment surface face each other.

10. The semiconductor laser device according to claim 7, wherein the attachment surface extends perpendicular to the mounting surface of the mounting carrier.

11. The semiconductor laser device according to claim 7,
wherein
the submount comprises a contact coating,
the contact coating forms at least two connection surfaces on the attachment surface for electrical contacting of the associated semiconductor laser,
the contact coating forms at least two electrical contact surfaces via which the submount is electrically connected to the mounting carrier, and
the at least two electrical contact surfaces each run parallel to the mounting surface of the mounting carrier.

12. The semiconductor laser device according to claim 1, wherein the semiconductor lasers each comprise a plurality of emission regions, and wherein the emission regions of all semiconductor lasers are arranged within an ellipse with a longitudinal axis of at most 500 μm and a transverse axis of at most 100 μm.

13. The semiconductor laser device according to claim 1, wherein the semiconductor laser device is configured to emit laser pulses with a pulse duration of at most 5 ns.

14. A semiconductor laser device comprising a plurality of semiconductor lasers, wherein
the semiconductor laser device comprises a mounting carrier with a mounting surface,
the semiconductor lasers are arranged on the mounting surface,
the semiconductor laser device comprises at least two driver components for driving the semiconductor lasers, and
the at least two driver components are arranged one above the other as seen in a vertical direction perpendicular to the mounting surface; and
wherein the semiconductor laser device comprises a carrier body, wherein at least one of the driver components is arranged in a recess of the carrier body and the carrier body is fastened to the mounting surface, and wherein the carrier body and the semiconductor lasers are arranged next to each other on the mounting surface.
